(19) United States
(12) Patent Application Publication
(10) Pub. No.: US 2026/0032970 A1
(43) Pub. Date: Jan. 29, 2026

(54) SEMICONDUCTOR DEVICE AND METHOD FOR FABRICATING THE SAME

(71) Applicant: SK hynix Inc., Gyeonggi-do (KR)

(72) Inventor: Chan Ho JUNG, Gyeonggi-do (KR)

(21) Appl. No.: 19/095,047

(22) Filed: Mar. 31, 2025

(30) Foreign Application Priority Data
Jul. 26, 2024 (KR) 10-2024-0099307

(51) Int. Cl. H10D 30/69; H10D 64/01; H10D 64/27; H10D 64/66; H10D 64/68; H10D 84/83

(52) U.S. Cl. CPC H10D 30/794; H10D 64/025; H10D 64/514; H10D 64/669; H10D 64/675; H10D 64/693; H10D 84/83

(57) ABSTRACT

A semiconductor device including a gate structure including a gate electrode which is formed over a substrate and includes a metal whose volume is increased when solidified, and a gate spacer formed on both sides of the gate structure. The performance of semiconductor devices is improved by applying a metal material to form the gate electrode whose volume increases when solidified and thereby applies a tensile stress to a channel.

### CROSS-REFERENCE TO RELATED APPLICATIONS

The present application claims priority under 35 U.S.C 119 (a) to Korean Patent Application No. 10-2024-0099307, filed on Jul. 26, 2024, which is incorporated herein by reference in its entirety.

### BACKGROUND

### 1. Field

Embodiments of the present disclosure relate generally to a semiconductor device, and more particularly, to a semiconductor device including a metal gate, and a method for fabricating the semiconductor device.

### 2. Description of the Related Art

As the feature size of MOS (Metal Oxide Semiconductor) transistors decreases, the length of a gate and the length of a channel formed below the gate may also decrease. Therefore, researchers and the industry are studying to increase the capacitance between the gate and the channel and improve the operation characteristics of the MOS transistors.

Thus, a method of replacing a polysilicon gate electrode with a metal gate electrode is being applied to improve device performance.

### SUMMARY

Embodiments of the present disclosure provide, a semiconductor device including a metal gate capable of applying a tensile stress to a channel formed in the substrate below the metal gate.

According to another embodiment of the present disclosure, a method for fabricating the semiconductor device is provided.

In accordance with an embodiment of the present disclosure, a semiconductor device includes a gate structure including a gate electrode formed over a substrate. The gate electrode includes a metal whose volume is increased when the metal is solidified. The semiconductor device may further include a gate spacer. The gate spacer may be formed on both sides of the gate structure.

In accordance with another embodiment of the present disclosure, a semiconductor device includes a substrate, a first gate structure, and a second gate structure. The substrate may include a first region and a second region. The first gate structure may include a first gate electrode including a metal whose volume is increased when solidified over the substrate of the first region. The second gate structure may include a second gate electrode over the substrate of the second region.

In accordance with another embodiment of the present disclosure, a method for fabricating a semiconductor device is provided which includes forming a dummy gate structure in which a gate dielectric layer and a dummy gate electrode are stacked over a substrate. The method may further include forming a gate spacer on both side walls of the dummy gate structure and removing the dummy gate electrode to form a trench. The method may further include forming a liquid metal layer having a volume that is increased when solidified and gap-filling the trench, and cooling the liquid metal layer to form a gate electrode.

In accordance with another embodiment of the present disclosure, a semiconductor device includes a gate structure including a gate electrode that is formed over a substrate and applies a tensile stress to a channel formed in the substrate below the gate structure, and a gate spacer formed on both sides of the gate structure.

In accordance with another embodiment of the present disclosure, a semiconductor device includes a substrate, a first gate structure, and a second gate structure. The substrate may include a first region and a second region. The first gate structure may include a first metal gate electrode over the substrate of the first region. The second gate structure may include a second gate electrode which is formed of a gate electrode that applies a tensile stress to a channel over the substrate of the second region.

In accordance with another embodiment of the present disclosure, a semiconductor device includes forming first and second dummy gate structures which include first and second gate dielectric layers and first and second dummy gate electrodes over a substrate including first and second regions, respectively. The method further may include forming first and second gate spacers on both side walls of the first and second dummy gate structures, respectively, removing the first and second dummy gate electrodes to form first and second trenches, respectively, forming a first metal gate electrode that gap-fills the first trench of the first region, forming a liquid metal layer that gap-fills the second trench of the second region and having a volume that is increased when solidified, and cooling the liquid metal layer. In accordance with another embodiment of the present disclosure, a semiconductor device includes a gate structure including a gate electrode that is formed over a substrate and includes a metal whose volume is increased when solidified; and a gate spacer formed on both sides of the gate structure, wherein the gate electrode applies a tensile stress to a channel formed in the substrate below the gate structure.

These and other features and advantages of the embodiments of the present disclosure will become better understood from the following drawings and detailed description.

### BRIEF DESCRIPTION OF THE DRAWINGS

FIG. 1 is a cross-sectional view illustrating a semiconductor device in accordance with an embodiment of the present disclosure.

FIGS. 2A to 2E are cross-sectional views illustrating a method for fabricating a semiconductor device in accordance with an embodiment of the present disclosure.

FIGS. 3 and 4 are cross-sectional views illustrating a semiconductor device in accordance with another embodiment of the present disclosure.

FIGS. 5A to 5L are process cross-sectional views illustrating a method for fabricating the semiconductor device shown in FIG. 4, according to an embodiment of the present disclosure.

FIG. 6 is a cross-sectional view illustrating a semiconductor device in accordance with another embodiment of the present disclosure.

FIGS. 7A to 7J are process cross-sectional views illustrating a method for fabricating the semiconductor device shown in FIG. 6, according to an embodiment of the present disclosure.

### DETAILED DESCRIPTION

Embodiments of the present disclosure will be described below in more detail with reference to the accompanying drawings. The embodiments of the present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

The drawings are not necessarily to scale and in some instances, proportions may have been exaggerated in order to clearly illustrate features of the embodiments. When a first layer is referred to as being ‘on’ a second layer or ‘on’ a substrate, it not only refers to a case where the first layer is formed directly on the second layer or the substrate but also a case where a third layer exists between the first layer and the second layer or the substrate.

The gate structures illustrated in the embodiments of the present disclosure may be Replacement Metal Gate (RMG) structures. An RMG structure refers to a structure that is formed by forming a dummy gate pattern and gate spacers on both side walls of the dummy gate pattern, and then replacing the dummy gate pattern with a metal gate.

FIG. 1 is a cross-sectional view illustrating a semiconductor device in accordance with an embodiment of the present disclosure.

Referring to FIG. 1, a gate structure GS may be formed over a substrate 101.

The substrate 101 may be any material that is suitable for semiconductor processing. The substrate 101 may include a semiconductor substrate. The substrate 101 may be formed of a material containing silicon. The substrate 101 may include silicon, monocrystalline silicon, polysilicon, amorphous silicon, silicon germanium, carbon-doped silicon, or any combination thereof. The substrate may be formed as a single layer or a multi-layer. The substrate 101 may also include another semiconductor material, such as germanium. The substrate 101 may also include a III/V-group semiconductor substrate, for example, a compound semiconductor substrate, such as gallium arsenide (GaAs). The substrate 101 may also include an SOI (Silicon-On-Insulator) substrate. According to an embodiment of the present disclosure, the substrate 101 may be an NMOS (N-type Metal Oxide Semiconductor) region.

The substrate 101 may include an active region 103 defined via isolation layer 102. The isolation layer 102 may be a Shallow Trench Isolation (STI) region that is formed by a trench etching process. The isolation layer 102 may be formed through a series of processes including forming a shallow trench in the substrate 101 and forming a dielectric material that gap-fills the shallow trench. The isolation layer 102 may include silicon oxide, silicon nitride, or a combination thereof.

The gate structure GS may include a stacked structure of an interface layer 104, a high-k layer 105 formed on the interface layer 104, and a gate electrode 108 formed on the high-k layer 105. A gate spacer 106 may be formed on both side walls of the gate structure GS and may cover the entire side walls of the gate structure GS.

The stacked structure of the interface layer 104 and the high-k layer 105 may be referred to as a ‘gate dielectric layer.’ The interface layer 104 may include a dielectric material. For example, the interface layer 104 may include silicon oxide, silicon oxynitride, or a combination thereof.

The high-k layer 105 may include a dielectric material having a higher dielectric constant than silicon oxide (SiO₂). The high-k layer 105 may have a dielectric constant of, for example, approximately 10 to 25. The high-k layer 105 may be referred to as a ‘high-k layer.’ For example, the high-k layer 105 may include hafnium oxide, hafnium oxynitride, hafnium silicon oxide, tantalum oxide, titanium oxide, yttrium oxide, lanthanum aluminum oxide, zirconium oxide, zirconium silicon oxide, aluminum oxide, and/or a combination thereof, however, the technical concepts and scope of the present disclosure are not limited to these materials only. Other materials having a dielectric constant in the above range may also be used.

The gate electrode 108 may be a replacement metal gate that is formed through an RMG process. The gate electrode 108 may include a metal material whose volume is increased when solidified. In this way, the gate electrode 108 may apply a tensile stress TS to a channel formed inside the substrate below the gate structure.

The gate electrode 108 may include a liquid metal material deposited in a liquid state at around the room temperature (e.g., approximately 15° C. to 45° C.). For example, the gate electrode 108 may include a gallium-based metal material. For example, the gallium-based metal material may include EGaIn (Eutectic Gallim-Indium), however, the technical concepts and scope of the present disclosure are not limited thereto. The gallium-based metal material may have an adjustable melting point that may be adjusted by changing the composition ratio of the gallium and indium in the alloy.

The gate spacer 106 may include, for example, silicon oxide or silicon nitride.

Doped regions 110 may be formed in the substrate 101 on both sides of the gate structure GS. According to an embodiment of the present disclosure, the substrate 101 may be an NMOS region, and the doped regions 110 may be doped with an N-type impurity. When the substrate 101 is an NMOS region, a P-type well may be formed in the active region 103. A channel may be formed between the doped regions 110 that are formed in the substrate 101 on both sides of the gate structure GS.

An inter-layer dielectric layer 107 may be formed over the substrate 101 excluding the gate structure GS. The inter-layer dielectric layer 107 may cover the side wall of the gate spacer 106 and expose the upper surface (also referred to as the top surface) of the gate structure GS. The inter-layer dielectric layer 107 may have the same height as that of the gate structure GS. The upper surface of the inter-layer dielectric layer 107 may be disposed at the same level as the upper surface of the gate structure GS.

As described above, by forming the gate electrode 108 of a material capable of applying a tensile stress to the channel, the mobility of electrons may be improved and the current may be increased, thereby improving the performance of a device. Also, an embodiment of the present disclosure may be able to reduce the damage that may occur due to a high-temperature process by forming the gate electrode 108 of a metal material that may be deposited at around the room temperature and has a melting point which may be adjusted according to the composition ratio.

According to another embodiment of the present disclosure, the gate structure GS may also be applied to a flexible device or a stretchable device.

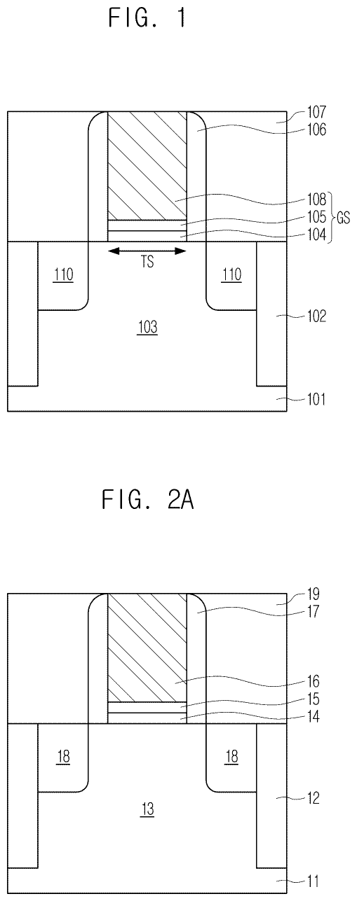

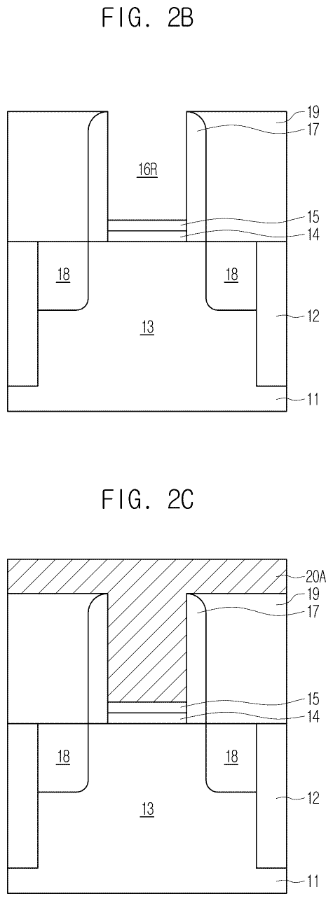

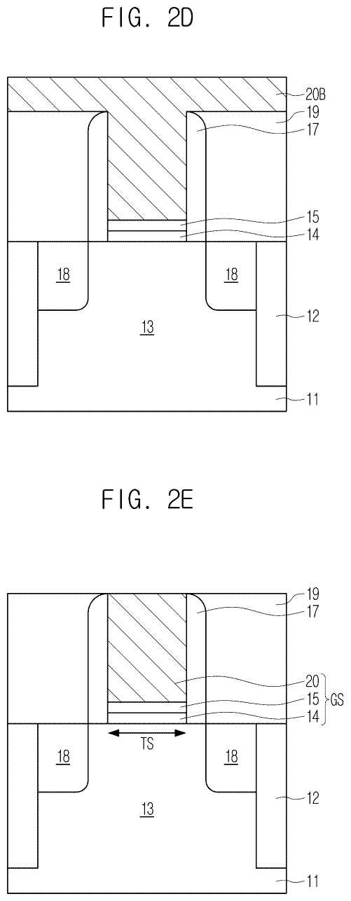

FIGS. 2A to 2E are cross-sectional views illustrating a method for fabricating a semiconductor device in accordance with an embodiment of the present disclosure. FIGS. 2A to 2E are process cross-sectional views illustrating a method for fabricating the semiconductor device of FIG. 1.

Referring to FIG. 2A, the substrate 11 may include an isolation layer 12 and an active region 13 defined by the isolation layer 12.

The substrate 11 may be any material suitable for semiconductor processing. The substrate 11 may include a semiconductor substrate. The substrate 11 may be formed of a material containing silicon. The substrate 11 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 11 may include another semiconductor material, such as germanium. The substrate 11 may include a III/V-group semiconductor substrate, for example, a compound semiconductor substrate such as gallium arsenide (GaAs). The substrate 11 may include an SOI (Silicon-On-Insulator) substrate. According to an of the present disclosure, the substrate 11 may be an NMOS (N-type Metal Oxide Semiconductor) region.

The isolation layer 12 may be formed by a Shallow Trench Isolation (STI) process which includes etching the substrate 11 to form an isolation trench (whose reference numeral is omitted). Then the isolation trench may be filled with a dielectric material to form the isolation layer 12. The isolation layer 12 may include silicon oxide, silicon nitride, or a combination thereof. Chemical Vapor Deposition (CVD) or another deposition process may be performed to fill the isolation trench with the dielectric material. A planarization process, such as Chemical Mechanical Polishing (CMP), may be additionally performed.

A dummy gate structure including a dummy gate 16 may be formed over the active region 13. The dummy gate structure may include a stacked structure of an interface layer 14, a high-k layer 15, and a dummy gate electrode 16. A gate spacer 17 may be formed on both side walls of the dummy gate structure. The dummy gate structure may be formed through a series of processes of sequentially stacking a dielectric material layer for interface, a high-k material layer, and a polysilicon layer for dummy gates, and etching them. The gate spacer 17 may be formed through a series of processes of forming a dielectric material layer for spacers that covers the dummy gate structure, and then etching the dielectric material layer for forming the spacers.

The stacked structure of the interface layer 14 and the high-k layer 15 may be referred to as a ‘gate dielectric layer.’ The interface layer 14 may include a dielectric material. For example, the interface layer 14 may include silicon oxide, silicon oxynitride, or a combination thereof.

The high-k layer 15 may include a dielectric material having a higher dielectric constant than silicon oxide (SiO₂). The high-k layer 15 may have, for example, a dielectric constant of approximately 10 to 25. The high-k layer 15 may be referred to as a ‘high-k layer.’ For example, the high-k layer 15 may include hafnium oxide, hafnium oxynitride, hafnium silicon oxide, tantalum oxide, titanium oxide, yttrium oxide, lanthanum oxide, lanthanum aluminum oxide, zirconium oxide, zirconium silicon oxide, aluminum oxide, and/or a combination thereof, however, the technical concepts and scope of the present disclosure are not limited thereto.

The dummy gate electrode 16 may include, for example, polysilicon.

The gate spacer 17 may include, for example, silicon oxide or silicon nitride.

Doped regions 18 may be formed in the substrate 11 on both sides of the dummy gate structure. Each doping region 18 may be formed between the dummy gate structure and the isolation layer 12. According to an embodiment of the present disclosure, the substrate 11 may be an NMOS region, and the doped regions 18 may be doped with an N-type impurity. When the substrate 11 is an NMOS region, a P-type well may be formed in the active region 13. A channel may be formed between the doped regions 18 formed in the substrate 11 on both sides of the dummy gate structure. The channel region under the dummy gate structure may be a region through which an N-type carrier moves.

Subsequently, an inter-layer dielectric layer 19 may be formed over the substrate 11. The inter-layer dielectric layer 19 may cover the side wall of the gate spacer 17 and expose the upper surface of the dummy gate structure. In order to expose the upper surface of the dummy gate structure, a planarization process may be performed after the inter-layer dielectric layer 19 is formed. Therefore, the inter-layer dielectric layer 19 may have the same height as that of the dummy gate structure. The upper surface of the inter-layer dielectric layer 19 may be disposed at the same level as the upper surface of the dummy gate structure.

The inter-layer dielectric layer 19 may include an oxide. For example, the inter-layer dielectric layer 19 may include silicon oxide, however, the technical concepts and scope of the present disclosure are not limited thereto. According to another embodiment of the present disclosure, the inter-layer dielectric layer 19 may be formed by stacking two or more dielectric layers.

Referring to FIG. 2B, the dummy gate electrode 16 (see FIG. 2A) may be removed. Accordingly, a trench 16R may be formed between the gate spacers 17. The trench 16R may expose the side surface of the gate spacer 17 and the upper surface of the high-k layer 15. As the dummy gate 16 is removed, the trench 16R, which is an empty space, may be formed, and a compressive stress may be applied to the channel.

Referring to FIG. 2C, a liquid metal layer 20A may be formed to gap-fill the trench 16R. The liquid metal layer 20A may be formed over the high-k layer 15 and the inter-layer dielectric layer 19.

The liquid metal layer 20A may include a metal material whose volume is increased when solidified. Also, the liquid metal layer 20A may include a liquid metal material that may be deposited in the liquid state at around the room temperature (e.g., approximately 15° C. to 45° C.). For example, the liquid metal layer 20A may include a gallium-based metal material. For example, the gallium-based metal material may include EGaIn (Eutectic Gallim-Indium), however, the technical concepts and scope of the present disclosure are not limited thereto. Also, the gallium-based metal material may have a melting point that may be adjusted according to the composition ratio of the alloy.

Since the liquid metal layer 20A may be deposited in the liquid state at around the room temperature, a high-temperature process may be unnecessary, and thus the damage to the device that may be caused due to the high-temperature process may be reduced.

Referring to FIG. 2D, the liquid metal layer 20A (see FIG. 2C) may be cooled to form a solid metal layer 20B. The cooling process may be performed at a temperature lower than the temperature at which the liquid metal layer 20A is formed.

The solid metal layer 20B may have a larger volume than the liquid metal layer 20A. Therefore, the solid metal layer 20B may apply a tensile stress TS to the channel.

As a comparative example, when the dummy gate electrode 16 is removed to form a replacement metal gate as illustrated in FIG. 2B, a trench 16R, which is an empty space, may be formed, and thus a stress may be inevitably applied from the surrounding structures, and ultimately a compressive stress may be applied to the channel. Also, the line width or volume of the trench 16R may be reduced due to the stress applied from the surrounding structures, and therefore, the applied compressive stress may still exist even after a metal gate electrode is formed in the trench 16R.

However, according to the embodiments of the present disclosure, not only the compressive stress applied from the surrounding structures may be relieved but also a tensile stress TS may be applied to the channel by using a metal material whose volume is increased when solidified.

Referring to FIG. 2E, a planarization process may be performed onto the solid metal layer 20B (see FIG. 2D) to form a gate electrode 20.

Therefore, a gate structure GS having a stacked structure of the interface layer 14, the high-k layer 15, and the gate electrode 20 may be formed. The gate structure GS may be referred to as a ‘replacement metal gate’.

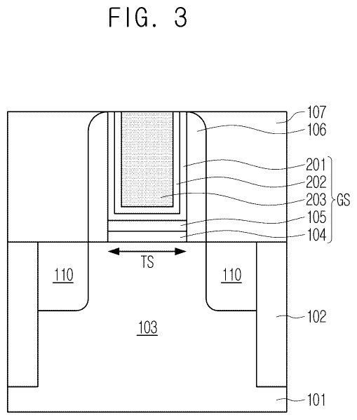

FIG. 3 is a cross-sectional view illustrating a semiconductor device in accordance with another embodiment of the present disclosure. FIG. 3 may include the same structure as that of FIG. 1 except for the gate electrode structure. The same reference numerals also appearing in FIG. 1 indicate the same structures. Therefore, a detailed description of them will be omitted or briefly described.

Referring to FIG. 3, a gate structure GS may be formed over a substrate 101.

According to an embodiment of the present disclosure, the substrate 101 may be an NMOS (N-type Metal Oxide Semiconductor) region. The substrate 101 may define an active region 103 through the isolation layer 102.

The gate structure GS may include a stacked structure of an interface layer 104, a high-k layer 105, a barrier layer 201, a work function layer 202, and a gate electrode 203. A gate spacer 106 may be formed on both side walls of the gate structure GS.

The stacked structure of the interface layer 104 and the high-k layer 105 may be referred to as a ‘gate dielectric layer.’ The interface layer 104 may include a dielectric material. For example, the interface layer 104 may include silicon oxide, silicon oxynitride, or a combination thereof.

The high-k layer 105 may include a dielectric material having a higher dielectric constant than silicon oxide (SiO₂). The high-k layer 105 may have a dielectric constant of, for example, approximately 10 to 25. The high-k layer 105 may be referred to as a ‘high-k layer.’ For example, the high-k layer 105 may include hafnium oxide, hafnium oxynitride, hafnium silicon oxide, tantalum oxide, titanium oxide, yttrium oxide, lanthanum oxide, lanthanum aluminum oxide, zirconium oxide, zirconium silicon oxide, aluminum oxide, and/or a combination thereof, however, the technical concepts and scope of the present disclosure are not limited thereto.

The barrier layer 201 may uniformly cover the upper surface of the high-k layer 105 and the inner wall of the gate spacer 106. The barrier layer 201 may have a ‘U’ shape. For example, the barrier layer 201 may include tantalum nitride, however, the technical concepts and scope of the present disclosure are not limited thereto.

The work function layer 202 may have its outer wall covered by the barrier layer 201. The work function layer 202 may be formed in a liner type over the barrier layer 201. The work function layer 202 may have a ‘U’ shape. According to an embodiment of the present disclosure, when the substrate 101 is an NMOS region, the work function layer 202 may be an N-type work function control layer. For example, the work function layer 202 may include at least one among titanium aluminide (TiAl) and titanium aluminum carbide (TiAlC).

The gate electrode 203 may be a replacement metal gate that is formed through the RMG process. The gate electrode 203 may include a metal material whose volume is increased when solidified. Therefore, the gate electrode 203 may apply a tensile stress TS to the channel. Also, the gate electrode 203 may include a liquid metal material that may be deposited in the liquid state at around the room temperature (e.g., approximately 15° C. to 45° C.). For example, the gate electrode 203 may include a gallium-based metal material. For example, the gallium-based metal material may include EGaIn (Eutectic Gallim-Indium), however, the technical concepts and scope of the present disclosure are not limited thereto. Also, the gallium-based metal material may have a melting point that may be adjusted according to the composition ratio of the alloy.

The gate spacer 106 may include, for example, silicon oxide or silicon nitride.

Doped regions 110 may be formed in the substrate 101 on both sides of the gate structure GS. According to an embodiment of the present disclosure, the substrate 101 may be an NMOS region, and the doped regions 110 may be doped with an N-type impurity. When the substrate 101 is an NMOS region, a P-type well may be formed in the active region 103. A channel may be formed between the doped regions 110 formed in the substrate 101 on both sides of the gate structure GS.

An inter-layer dielectric layer 107 may be formed over the substrate 101 excluding the gate structure GS. The inter-layer dielectric layer 107 may cover the side wall of the gate spacer 106 and expose the upper surface of the gate structure GS. The inter-layer dielectric layer 107 may have the same height as that of the gate structure GS. The upper surface of the inter-layer dielectric layer 107 may be disposed at the same level as the upper surface of the gate structure GS.

As above, by forming the gate electrode 203 of a material capable of applying a tensile stress to the channel, the mobility of electrons may be improved and the current may be increased, thereby improving the performance of the device. Also, according to the embodiments of the present disclosure, the damage that may be caused due to the high-temperature process may be reduced by forming the gate electrode 203 of a metal material that may be deposited at around the room temperature and has a melting point which may be adjusted according to the composition ratio.

According to another embodiment of the present disclosure, the gate structure GS may also be applied to a flexible device or a stretchable device.

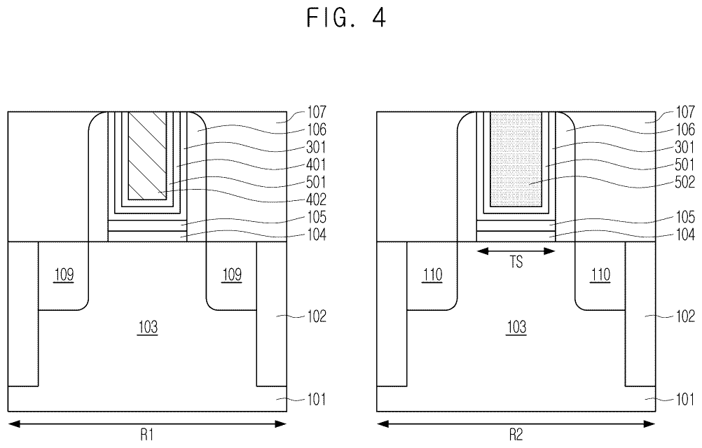

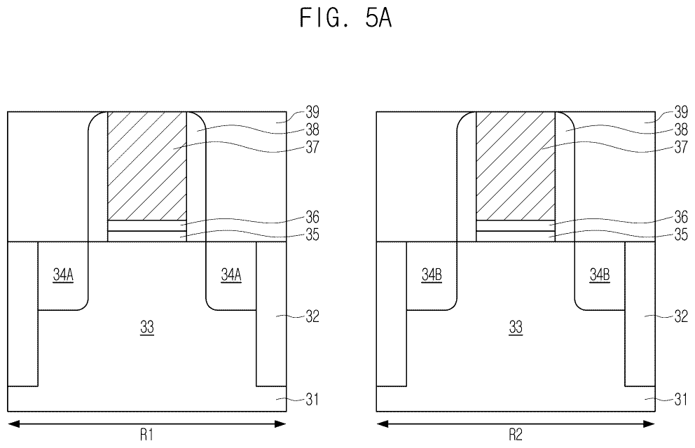

FIG. 4 is a cross-sectional view illustrating a semiconductor device in accordance with another embodiment of the present disclosure.

Referring to FIG. 4, the substrate 101 may include a first region R1 and a second region R2. The first region R1 and the second region R2 may be coupled to each other or may be separated from each other. For example, the first region R1 may be a PMOS region where a P-type transistor is formed, and the second region R2 may be an NMOS region where an N-type transistor is formed, however, the technical concepts and scope of the present disclosure are not limited thereto.

A first metal gate structure may be formed over the substrate of the first region R1, and a second metal gate structure may be formed over the substrate of the second region R2. The first metal gate structure may be referred to as a ‘PMOS gate’ or a ‘PMOS replacement metal gate’. The second gate structure may be referred to as an ‘NMOS gate’ or an ‘NMOS replacement metal gate’.

The substrate 101 may be any material suitable for semiconductor processing. The substrate 101 may include a semiconductor substrate. The substrate 101 may be formed of a material containing silicon. The substrate 101 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 101 may also include another semiconductor material, such as germanium. The substrate 101 may also include a III/V-group semiconductor substrate, for example, a compound semiconductor substrate, such as gallium arsenide (GaAs). The substrate 101 may also include an SOI (Silicon-On-Insulator) substrate.

The substrate 101 may define an active region 103 through an isolation layer 102. The isolation layer 102 may divide the substrate 101 into a first region R1 and a second region R2. The isolation layer 102 may be a shallow trench isolation (STI) region that is formed by a trench etching process. The isolation layer 102 may be formed through a series of processes of forming a shallow trench in the substrate 101 and forming a dielectric material to gap-fill the shallow trench. The isolation layer 102 may include silicon oxide, silicon nitride, or a combination thereof.

The first metal gate structure and the second metal gate structure may include the same structure except for the gate electrode material. The first metal gate structure may include a stacked structure of an interface layer 104, a high-k layer 105, a barrier layer 301, a first work function layer 401, a second work function layer 501, and a first metal gate electrode 402. The second metal gate structure may include a stacked structure of an interface layer 104, a high-k layer 105, a barrier layer 301, a second work function layer 502, and a second metal gate electrode 502.

A gate spacer 106 may be formed on both side walls of each of the first metal gate structure and the second metal gate structure.

The stacked structure of the interface layer 104 and the high-k layer 105 may be referred to as a ‘gate dielectric layer.’ The interface layer 104 may include a dielectric material. For example, the interface layer 104 may include silicon oxide, silicon oxynitride, or a combination thereof.

The high-k layer 105 may include a dielectric material having a higher dielectric constant than that of silicon oxide (SiO₂). The high-k layer 105 may have a dielectric constant of, for example, approximately 10 to 25. The high-k layer 105 may be referred to as a ‘high-k layer.’ For example, the high-k layer 105 may include hafnium oxide, hafnium oxynitride, hafnium silicon oxide, tantalum oxide, titanium oxide, yttrium oxide, lanthanum oxide, lanthanum aluminum oxide, zirconium oxide, zirconium silicon oxide, aluminum oxide, and/or a combination thereof, however, the technical concepts and scope of the present disclosure are not limited thereto.

The barrier layer 301 may uniformly cover the upper surface of the high-k layer 105 and the inner wall of the gate spacer 106. The barrier layer 301 may have a ‘U’ shape. For example, the barrier layer 301 may include tantalum nitride, however, the technical concepts and scope of the present disclosure are not limited thereto.

The first work function layer 401 may be selectively formed over the barrier layer 301 of the first region R1. The first work function layer 401 may be formed in a liner type over the barrier layer 301 of the first region R1. The first work function layer 401 may have a ‘U’ shape. According to an embodiment of the present disclosure, when the first region R1 is a PMOS region, the first work function layer 401 may be a P-type work function control layer. For example, the first work function layer 401 may include titanium nitride (TIN), however, the technical concepts and scope of the present disclosure are not limited thereto.

The second work function layer 501 may be formed over the first work function layer 401 of the first region R1 and over the barrier layer 301 of the second region R2. The second work function layer 501 may have a ‘U’ shape. In the first region R1, the second work function layer 501 may be formed over the first work function layer 401 in a liner type. In the second region R2, the second work function layer 501 may be formed over the barrier layer 301 in a liner type. According to an embodiment of the present disclosure, when the first region R1 is a PMOS region and the second region R2 is an NMOS region, the second work function layer 501 may be an N-type work function control layer. For example, the second work function layer 501 may include at least one among TiAl and TiAlC.

The first metal gate electrode 402 may be formed over the second work function layer 501 of the first region R1. The upper surface of the first metal gate electrode 401 may be disposed at the same level as the upper surface of the inter-layer dielectric layer 107.

The first metal gate electrode 401 may include a low-resistance material, such as tungsten or aluminum. According to another embodiment of the present disclosure, the first metal gate electrode 401 may be a stacked structure of a diffusion barrier layer and a low-resistance material. For example, the diffusion barrier layer may include titanium nitride.

The second metal gate electrode 502 may include a metal material whose volume is increased when solidified. Therefore, the second metal gate electrode 502 may apply a tensile stress TS to the channel. Also, the second metal gate electrode 502 may include a liquid metal material that may be deposited in the liquid state at around the room temperature (e.g., approximately 15° C. to 45° C.). For example, the second metal gate electrode 502 may include a gallium-based metal material. For example, the gallium-based metal material may include EGaIn (Eutectic Gallim-Indium), however, the technical concepts and scope of the present disclosure are not limited thereto. Also, the gallium-based metal material may have a melting point which may be adjusted according to the composition ratio of the alloy.

The gate spacer 106 may include, for example, silicon oxide or silicon nitride.

First doped regions 109 may be formed over the substrate 101 on both sides of the first metal gate structure. Also, second doped regions 110 may be formed over the substrate 101 on both sides of the second metal gate structure. The first doped regions 109 may be formed in the first region R1. The second doped regions 110 may be formed in the second region R2. According to an embodiment of the present disclosure, when the first region R1 is a PMOS region, the first doped regions 109 may be doped with a P-type impurity. Here, an N-type well may be formed in the active region 103. Also, when the second region R2 is an NMOS region, the second doped regions 110 may be doped with an N-type impurity. Here, a P-type well may be formed in the active region 103.

A channel may be formed between the first doped regions 109 that are formed over the substrate 101 on both sides of the first metal gate structure. Also, a channel may be formed between the second doped regions 110 that are formed over the substrate 101 on both sides of the second metal gate structure. In particular, according to an embodiment of the present disclosure, a tensile stress TS may be applied to the channel by forming the second metal gate electrode 502 of a metal material whose volume is increased when solidified.

An inter-layer dielectric layer 107 may be formed over the substrate 101 excluding the first and second metal gate structures. The inter-layer dielectric layer 107 may cover the side wall of the gate spacer 106 and expose the upper surface of the gate structure. The inter-layer dielectric layer 107 may have the same height as that of the gate structure. The upper surface of the inter-layer dielectric layer 107 may be disposed at the same level as the upper surface of the gate structure.

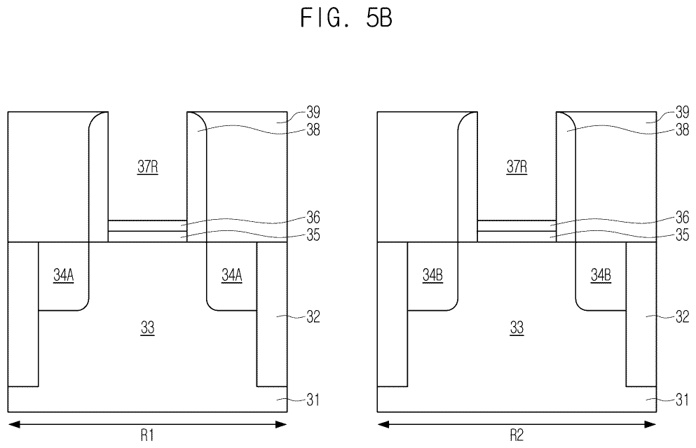

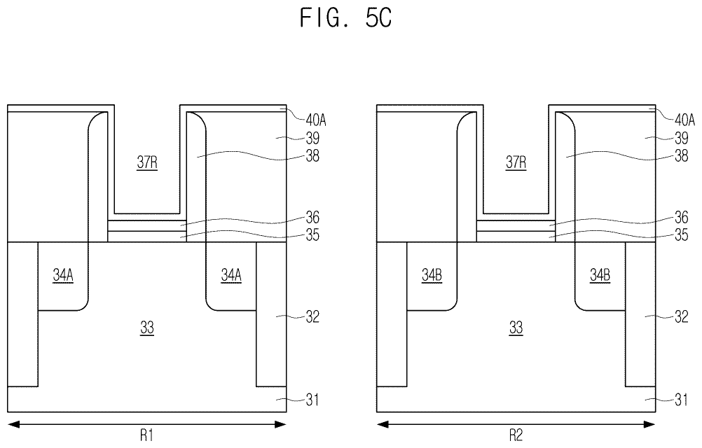

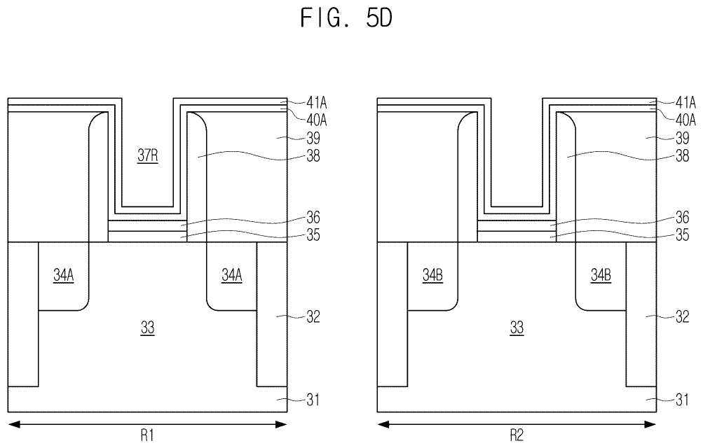

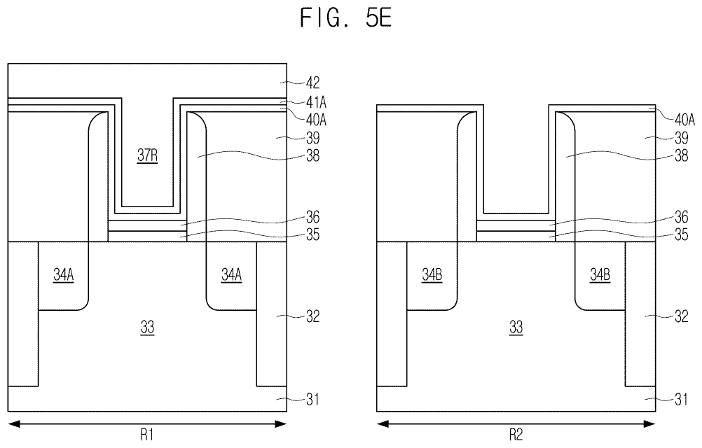

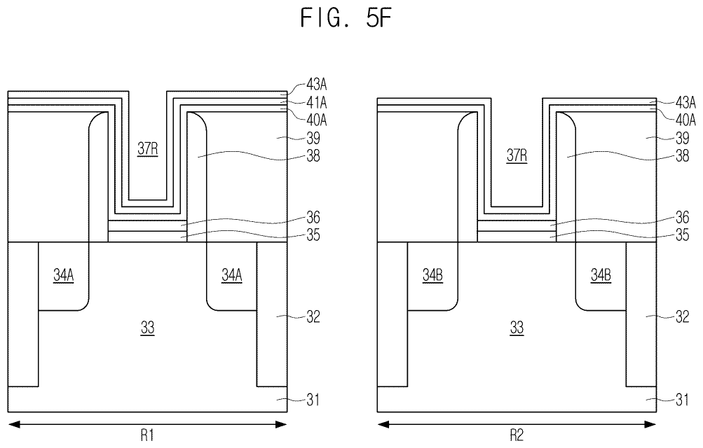

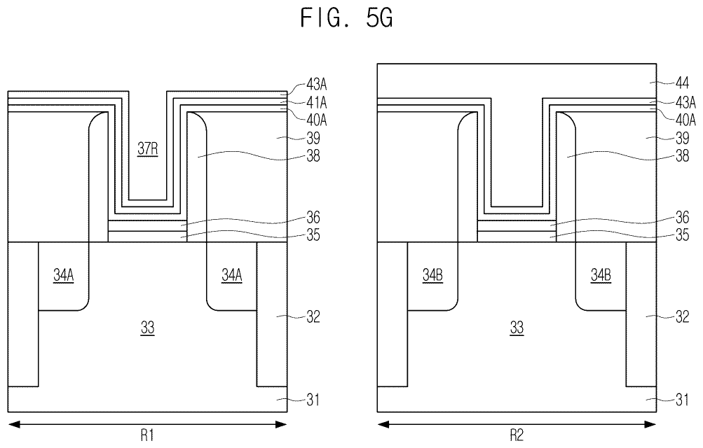

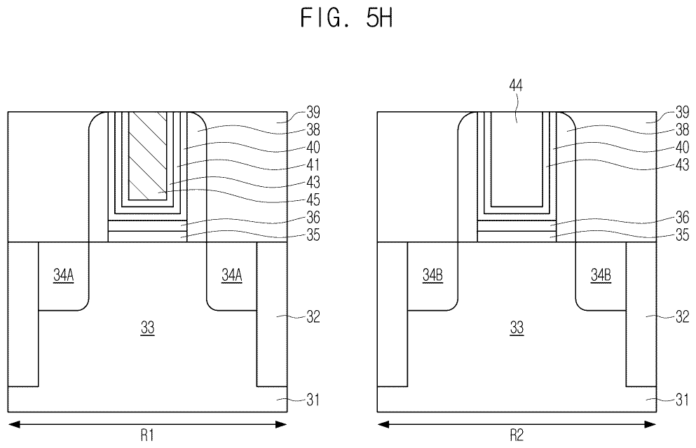

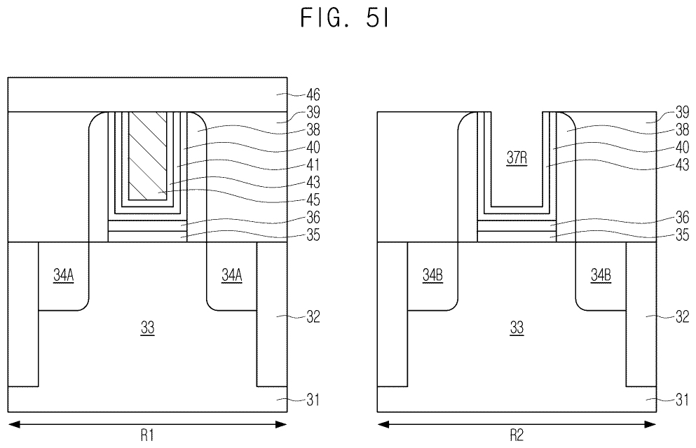

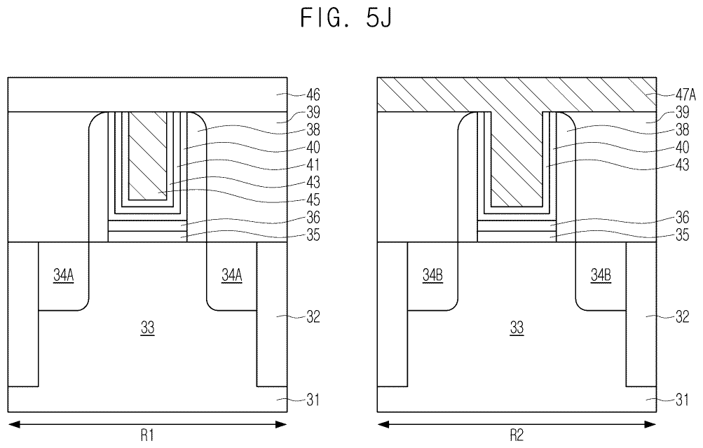

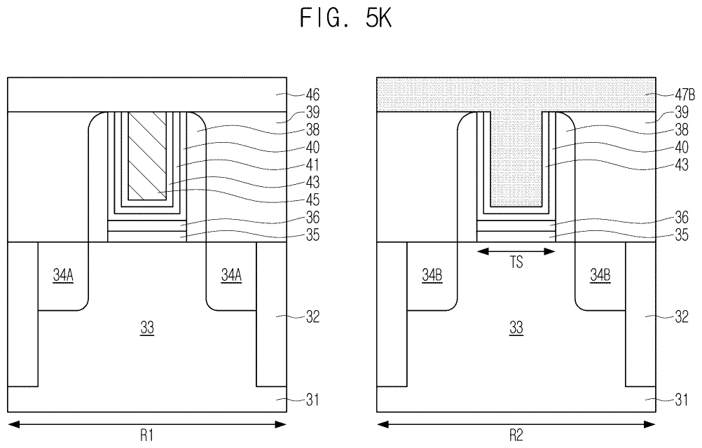

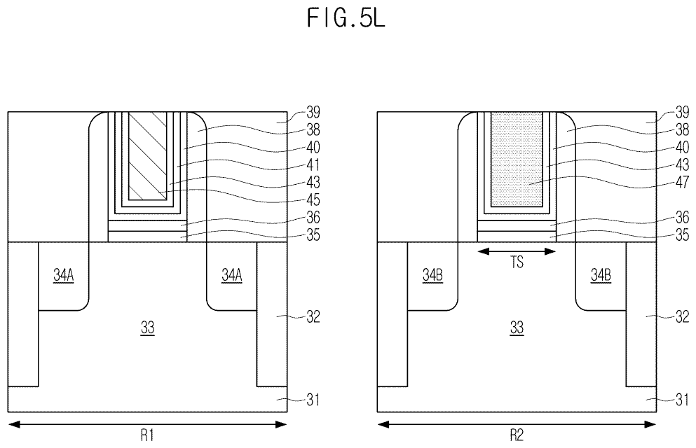

FIGS. 5A to 5L are process cross-sectional views illustrating a method for fabricating the semiconductor device shown in FIG. 4, according to an embodiment of the present disclosure.

Referring to FIG. 5A, the substrate 31 may include an isolation layer 32 and an active region 33 that is defined by the isolation layer 32.

The substrate 31 may include a first region R1 and a second region R2. The first region R1 and the second region R2 may be coupled to each other or may be separated from each other. For example, the first region R1 may be a PMOS region where a P-type transistor is formed, and the second region R2 may be an NMOS region where an N-type transistor is formed, however, the technical concepts and scope of the present disclosure are not limited thereto.

The substrate 31 may be any material suitable for semiconductor processing. The substrate 31 may include a semiconductor substrate. The substrate 31 may be formed of a material containing silicon. The substrate 31 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 31 may also include another semiconductor material, such as germanium. The substrate 31 may also include a III/V-group semiconductor substrate, for example, a compound semiconductor substrate, such as gallium arsenide (GaAs). The substrate 31 may also include an SOI (Silicon-On-Insulator) substrate. According to an embodiment of the present disclosure, the substrate 31 may be an NMOS (N-type Metal Oxide Semiconductor) region.

The isolation layer 32 may be formed by a Shallow Trench Isolation (STI) process. The STI process may be as follows. The substrate 31 may be etched to form an isolation trench (whose reference numeral is omitted). The isolation trench may be filled with a dielectric material to form an isolation layer 32. The isolation layer 32 may include silicon oxide, silicon nitride, or a combination thereof. Chemical Vapor Deposition (CVD) or another deposition process may be performed to fill the isolation trench with the dielectric material. A planarization process such as Chemical Mechanical Polishing (CMP) may additionally be performed.

First and second dummy gate structures each including a dummy gate 37 may be formed over the substrate 31 of the first and second regions R1 and R2. The first dummy gate structure and the second dummy gate structure may be formed to have the same structure in the first region R1 and the second region R2, respectively. Each of the first and second dummy gate structures may include a stacked structure of an interface layer 35, a high-k layer 36, and a dummy gate electrode 37. A gate spacer 38 may be formed on both side walls of each of the first and second dummy gate structures. Each of the first and second dummy gate structures may be formed through a series of processes of sequentially stacking a dielectric material layer for interface, a high-k material layer and a polysilicon layer for dummy gates, and etching them. The gate spacers 38 may be formed through a series of processes of forming a dielectric material layer for spacers that covers each of the first and second dummy gate structures, and then etching the dielectric material layer for forming the spacers.

The stacked structure of the interface layer 35 and the high-k layer 36 may be referred to as a ‘gate dielectric layer.’ The interface layer 35 may include a dielectric material. For example, the interface layer 35 may include silicon oxide, silicon oxynitride, or a combination thereof.

The high-k layer 36 may include a dielectric material having a higher dielectric constant than silicon oxide (SiO₂). The high-k layer 36 may have a dielectric constant of, for example, approximately 10 to 25. The high-k layer 36 may be referred to as a ‘high-k layer.’ For example, the high-k layer 36 may include hafnium oxide, hafnium oxynitride, hafnium silicon oxide, tantalum oxide, titanium oxide, yttrium oxide, lanthanum oxide, lanthanum aluminum oxide, zirconium oxide, zirconium silicon oxide, aluminum oxide, and/or a combination thereof, however, the technical concepts and scope of the present disclosure are not limited thereto.

The dummy gate electrode 37 may include, for example, polysilicon.

The gate spacer 38 may include, for example, silicon oxide or silicon nitride.

First doped regions 34A may be formed over the substrate 31 on both sides of the first dummy gate structure. Also, second doped regions 34B may be formed over the substrate 31 on both sides of the second dummy gate structure. The first doped regions 34A may be formed in the first region R1. The second doped regions 34B may be formed in the second region R2. According to an embodiment of the present disclosure, when the first region R1 is a PMOS region, the first doped regions 34A may be doped with a P-type impurity. Here, an N-type well may be formed in the active region 33. Also, when the second region R2 is an NMOS region, the second doped regions 34B may be doped with an N-type impurity. Here, a P-type well may be formed in the active region 33.

Subsequently, an inter-layer dielectric layer 39 may be formed over the substrate 31 of the first and second regions R1 and R2. The inter-layer dielectric layer 39 may cover the side wall of the gate spacer 37 and expose the upper surfaces of the first and second dummy gate structures. In order to expose the upper surfaces of the first and second dummy gate structures, a planarization process may be performed after the inter-layer dielectric layer 39 is formed. As a result, the inter-layer dielectric layer 39 may have the same height as those of the first and second dummy gate structures. The upper surface of the inter-layer dielectric layer 39 may be disposed at the same level as the upper surfaces of the first and second dummy gate structures.

The inter-layer dielectric layer 39 may include an oxide. For example, the inter-layer dielectric layer 39 may include silicon oxide, however, the technical concepts and scope of the present disclosure are not limited thereto. According to another embodiment of the present disclosure, the inter-layer dielectric layer 39 may be formed by stacking two or more dielectric layers.

Referring to FIG. 5B, the dummy gate electrodes 37 (see FIG. 5A) may be removed from the first and second regions R1 and R2. As a result, a trench 37R may be formed between the gate spacers 38 of each of the first and second regions R1 and R2. The trench 37R may expose the side surface of the gate spacer 38 and the upper surface of the high-k layer 36. As the dummy gate electrode 37 is removed, the trench 37R, which is an empty space, may be formed, and a compressive stress may be applied to the channel.

Referring to FIG. 5C, a barrier material layer 40A may be formed in the trench 37R of each of the first and second regions R1 and R2. The barrier material layer 40A may be formed conformally along the inner wall and the bottom surface of the trench 37R. The barrier material layer 40A may uniformly cover the upper surface of the high-k layer 36 and the inner wall of the gate spacer 37. For example, the barrier material layer 40A may include tantalum nitride (TaN), however, the technical concepts and scope of the present disclosure are not limited thereto.

Referring to FIG. 5D, a first work function material layer 41A may be formed over the barrier material layer 40A of each of the first region R1 and the second region R2.

The first work function material layer 41A may be formed in a liner type over the barrier material layer 40A. For example, the first work function material layer 41A may include titanium nitride (TiN), however, the technical concepts and scope of the present disclosure are not limited thereto.

Referring to FIG. 5E, a first mask layer 42 may be formed over the first work function material layer 41A of the first region R1. Subsequently, the first work function material layer 41A of the second region R1 may be removed. Accordingly, over the high-k layer 36, a stacked structure of the barrier material layer 40A and the first work function material layer 41A may be formed in the first region R1, and the barrier material layer 40A may be formed in the second region R2.

According to an embodiment of the present disclosure, when the first region R1 is a PMOS region, the first work function material layer 41A may be a P-type work function control layer.

Subsequently, the first mask layer 42 may be removed. When the first mask layer 42 includes a photosensitive layer, the first mask layer 42 may be removed by an oxygen strip process.

Referring to FIG. 5F, a second work function material layer 43A may be formed over the first work function material layer 41A of the first region R1 and over the barrier material layer 40A of the second region R2.

The second work function material layer 43A may be formed in a liner type. According to an embodiment of the present disclosure, when the first region R1 is a PMOS region and the second region R2 is an NMOS region, the second work function material layer 43A may be an N-type work function control layer. For example, the second work function material layer 43A may include at least one among TiAl and TiAlC.

Referring to FIG. 5G, a second mask layer 44 may be formed over the second work function material layer 43A of the second region R2. The second mask layer 44 may serve as a sacrificial layer for selectively forming a first metal gate electrode in the first region R1. For example, the second mask layer 44 may include a photosensitive layer, however, the technical concepts and scope of the present disclosure are not limited thereto.

Referring to FIG. 5H, a first metal gate structure may be formed in the first region R1.

The first metal gate structure may be formed through a series of processes of forming a gate electrode material over the second work function material layer 43A (see FIG. 5G) of the first region R1 and planarizing the gate electrode material to expose the upper surface of the inter-layer dielectric layer 39. Accordingly, the first metal gate structure may have the same height as that of the inter-layer dielectric layer 39. The upper surface of the first metal gate structure may be disposed at the same level as the upper surface of the inter-layer dielectric layer 39.

The first metal gate structure may include a stacked structure of an interface layer 35, a high-k layer 36, a barrier layer 40, a first work function layer 41, a second work function layer 43, and a first metal gate electrode.

For example, the first metal gate electrode 45 may include a low-resistance material, such as tungsten or aluminum. According to another embodiment of the present disclosure, the first metal gate electrode 45 may be a stacked structure of a diffusion barrier layer and a low-resistance material. For example, the diffusion barrier layer may include titanium nitride.

In the planarization process for forming the first metal gate structure, the second mask layer 44, the second work function material layer 43A (see FIG. 5G), and the barrier material layer 40A (see FIG. 5G) may be etched together to expose the upper surface of the inter-layer dielectric layer 39 in the second region R2. Hereinafter, the second work function material layer 43A (see FIG. 5G) and the barrier material layer 40A (see FIG. 5G) that are etched during the planarization process may be referred to as a ‘second work function layer 43’ and a ‘barrier layer 40’, respectively.

Referring to FIG. 5I, a third mask layer 46 may be formed over the first metal gate structure and the inter-layer dielectric layer 39 in the first region R1.

Subsequently, the second mask layer 44 (see FIG. 5H) of the second region R2 may be removed to expose the inner wall and the bottom surface of the second work function layer 43 in the trench 37R.

Referring to FIG. 5J, a liquid metal layer 47A that gap-fills the trench 37R may be formed over the second work function layer 43. The liquid metal layer 47A may include a metal material whose volume is increased when solidified. Also, the liquid metal layer 47A may include a liquid metal material that may be deposited in the liquid state at around the room temperature (e.g., approximately 15° C. to 45° C.). For example, the liquid metal layer 47A may include a gallium-based metal material. For example, the gallium-based metal material may include EGaIn (Eutectic Gallim-Indium), however, the technical concepts and scope of the present disclosure are not limited thereto. Also, the gallium-based metal material may have a melting point that may be adjusted according to the composition ratio of the alloy.

Since the liquid metal layer 47A may be deposited in the liquid state at around the room temperature, a high-temperature process may be unnecessary, and thus the damage to the device that may be caused due to the high-temperature process may be reduced.

Referring to FIG. 5K, a solid metal layer 47B may be formed by cooling the liquid metal layer 47A (see FIG. 5J). The cooling process may be performed at a temperature lower than the temperature at which the liquid metal layer 47A is formed.

The solid metal layer 47B may have a larger volume than the liquid metal layer 47A. Therefore, the solid metal layer 47B may apply a tensile stress TS to the channel formed below the metal gate structure between the second doped regions 34B.

Referring to FIG. 5L, a second metal gate structure may be formed by performing a planarization process onto the solid metal layer 47B to remove any solid metal layer 47B positioned above a plane defined by the top surface of the inter-layer dielectric layer 39 (see FIG. 5K).

The second metal gate structure may include a stacked structure of the interface layer 35, the high-k layer 36, the barrier layer 40, the second work function layer 43, and a second metal gate electrode 47.

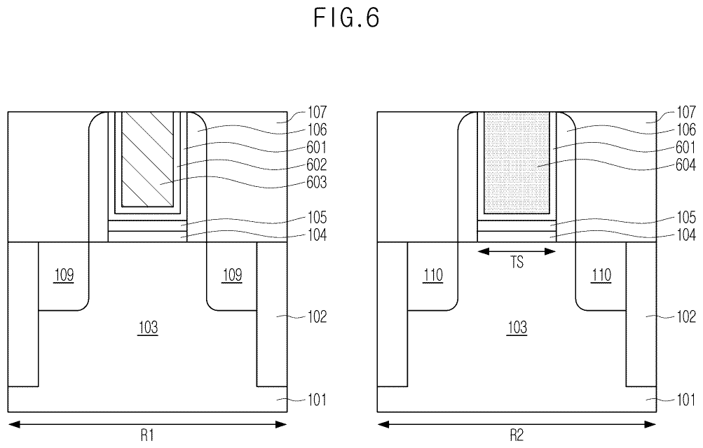

FIG. 6 is a cross-sectional view illustrating a semiconductor device in accordance with another embodiment of the present disclosure. FIG. 6 may include the same structure as that of FIG. 4, except for the structure of the metal gate structure. FIG. 6 may include a structure in which the second work function layer is omitted from the metal gate structure of FIG. 4. The same reference numerals of FIG. 6 also appearing in FIG. 4 may indicate the same structures, and, therefore, a detailed description thereof may be omitted or may be brief.

Referring to FIG. 6, the substrate 101 may include a first region R1 and a second region R2. The first region R1 and the second region R2 may be coupled to each other or may be separated from each other. For example, the first region R1 may be a PMOS region where a P-type transistor is formed, and the second region R2 may be an NMOS region where an N-type transistor is formed, however, the technical concepts and scope of the present disclosure are not limited thereto.

A first gate structure may be formed over the substrate of the first region R1. A second gate structure may be formed over the substrate of the second region R2. The first gate structure may be referred to as a ‘PMOS gate’ or a ‘PMOS replacement metal gate’. The second gate structure may be referred to as an ‘NMOS gate’ or an ‘NMOS replacement metal gate’.

The substrate 101 may define an active region 103 through an isolation layer 102. The isolation layer 102 may divide the substrate 101 into the first region R1 and the second region R2.

The first gate structure and the second gate structure may include the same structure except for a gate electrode material. The first gate structure and the second gate structure may include different gate electrode materials. The first gate structure may include a stacked structure of an interface layer 104, a high-k layer 105, a barrier layer 601, a work function layer 602, and a first metal gate electrode 603. The second gate structure may include a stacked structure of an interface layer 104, a high-k layer 105, a barrier layer 601, and a second metal gate electrode 604.

A gate spacer 106 may be formed on both side walls of each of the first gate structure and the second gate structure and may cover both side walls of each of the first gate structure and the second gate structure.

The stacked structure of the interface layer 104 and the high-k layer 105 may be referred to as a ‘gate dielectric layer.’ The interface layer 104 may include a dielectric material. For example, the interface layer 104 may include silicon oxide, silicon oxynitride, or a combination thereof.

The high-k layer 105 may include a dielectric material having a higher dielectric constant than silicon oxide (SiO₂). The high-k layer 105 may have a dielectric constant of, for example, approximately 10 to 25. The high-k layer 105 may be referred to as a ‘high-k layer.’ For example, the high-k layer 105 may include hafnium oxide, hafnium oxynitride, hafnium silicon oxide, tantalum oxide, titanium oxide, yttrium oxide, lanthanum oxide, lanthanum aluminum oxide, zirconium oxide, zirconium silicon oxide, aluminum oxide, and/or a combination thereof, however, the technical concepts and scope of the present disclosure are not limited thereto.

The barrier layer 601 may uniformly cover the upper surface of the high-k layer 105 and the inner wall of the gate spacer 106. The barrier layer 301 may have a ‘U’ shape. For example, the barrier layer 601 may include tantalum nitride, however, the technical concepts and scope of the present disclosure are not limited thereto.

The work function layer 602 may be selectively formed over the barrier layer 601 of the first region R1. The work function layer 602 may be formed in a liner type over the barrier layer 601 of the first region R1. The work function layer 602 may have a ‘U’ shape. According to an embodiment of the present disclosure, when the first region R1 is a PMOS region, the work function layer 602 may be a P-type work function control layer. For example, the work function layer 602 may include titanium nitride (TIN), however, the technical concepts and scope of the present disclosure are not limited thereto.

The first metal gate electrode 603 may be formed over the work function layer 602 of the first region R1. The upper surface of the first metal gate electrode 603 may be disposed at the same level as the upper surface of the inter-layer dielectric layer 107.

The first metal gate electrode 603 may include a low-resistance material, such as tungsten or aluminum. According to another embodiment of the present disclosure, the first metal gate electrode 603 may be a stacked structure of a diffusion barrier layer and a low-resistance material. For example, the diffusion barrier layer may include titanium nitride.

The second metal gate electrode 604 may include a metal material whose volume is increased when solidified. Therefore, the second metal gate electrode 604 may apply a tensile stress TS to the channel formed below the second metal gate structure between the second doped regions 110. Also, the second metal gate electrode 604 may include a liquid metal material that may be deposited in the liquid state at around the room temperature (e.g., approximately 15° C. to 45° C.). For example, the second metal gate electrode 604 may include a gallium-based metal material. For example, the gallium-based metal material may include EGaIn (Eutectic Gallim-Indium), however, the technical concepts and scope of the present disclosure are not limited thereto. Also, the gallium-based metal material may have a melting point that may be adjusted according to the composition ratio of the alloy.

The gate spacer 106 may include, for example, silicon oxide or silicon nitride.

First doped regions 109 may be formed over the substrate 101 on both sides of the first gate structure. Also, second doped regions 110 may be formed over the substrate 101 on both sides of the second gate structure. The first doped regions 109 may be formed in the first region R1. The second doped regions 110 may be formed in the second region R2. According to an embodiment of the present disclosure, when the first region R1 is a PMOS region, the first doped regions 109 may be doped with a P-type impurity. Here, an N-type well may be formed in the active region 103. Also, when the second region R2 is an NMOS region, the second doped regions 110 may be doped with an N-type impurity. Here, a P-type well may be formed in the active region 103.

A channel may be formed between the first doped regions 109 that are formed over the substrate 101 on both sides of the first gate structure. Also, a channel may be formed between the second doped regions 110 that are formed over the substrate 101 on both sides of the second gate structure. In particular, according to the embodiments of the present disclosure, a tensile stress TS may be applied to the channel by forming the second metal gate electrode 502 of a metal material whose volume is increased when solidified.

An inter-layer dielectric layer 107 may be formed over the substrate 101 excluding the first and second gate structures. The inter-layer dielectric layer 107 may cover the side wall of the gate spacer 106 and expose the upper surface of the gate structure. The inter-layer dielectric layer 107 may have the same height as that of the gate structure. The upper surface of the inter-layer dielectric layer 107 may be disposed at the same level as the upper surface of the gate structure.

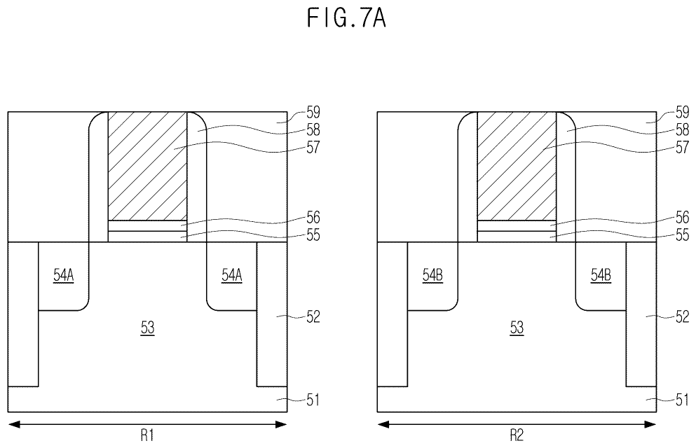

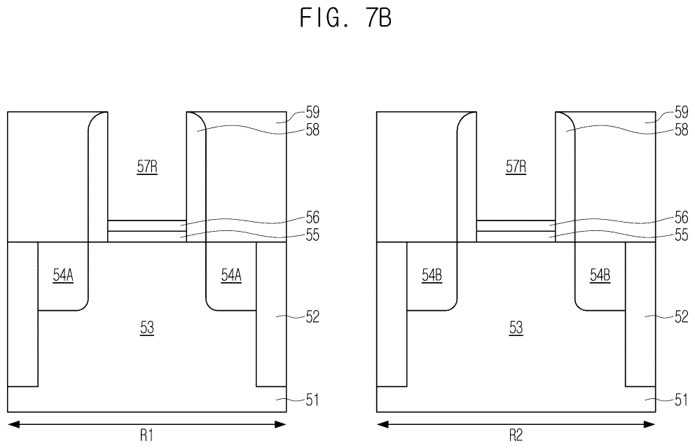

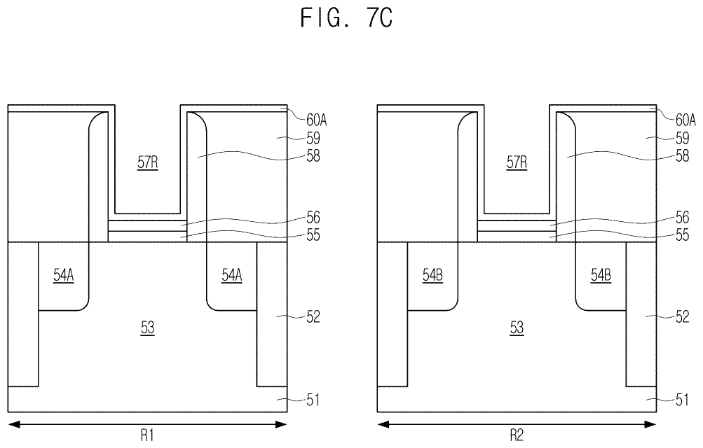

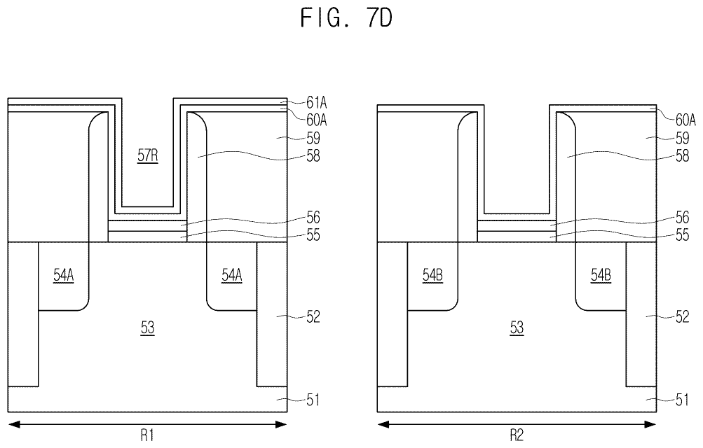

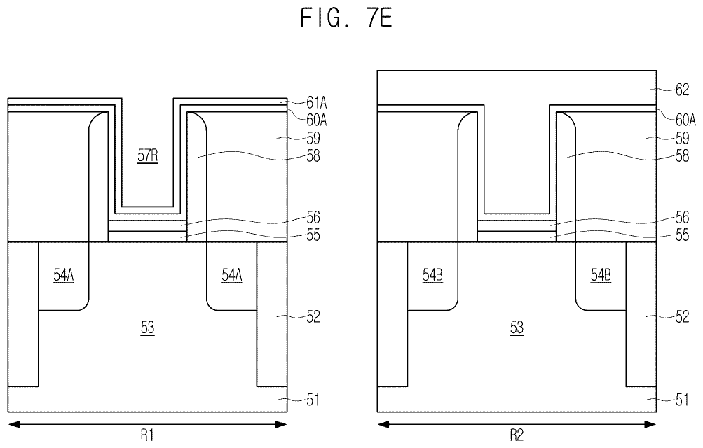

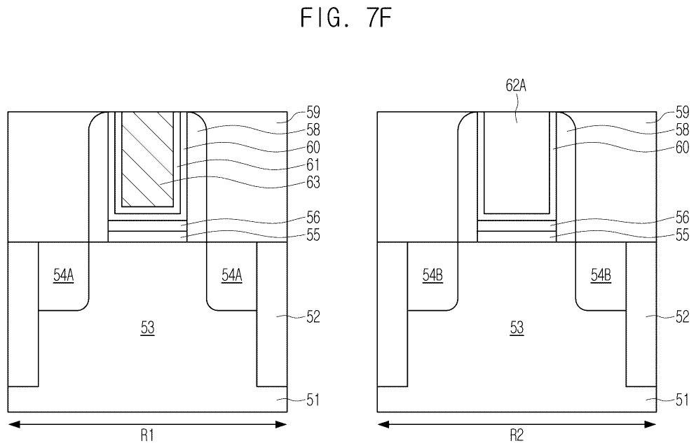

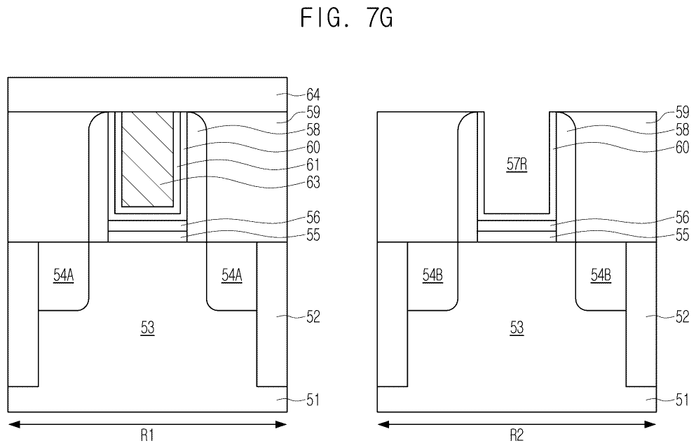

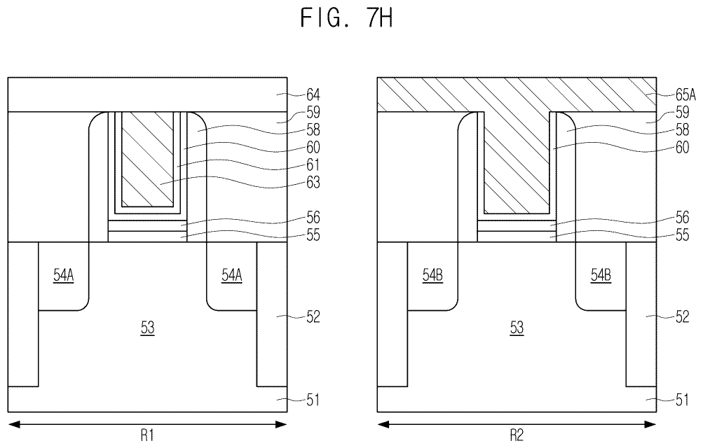

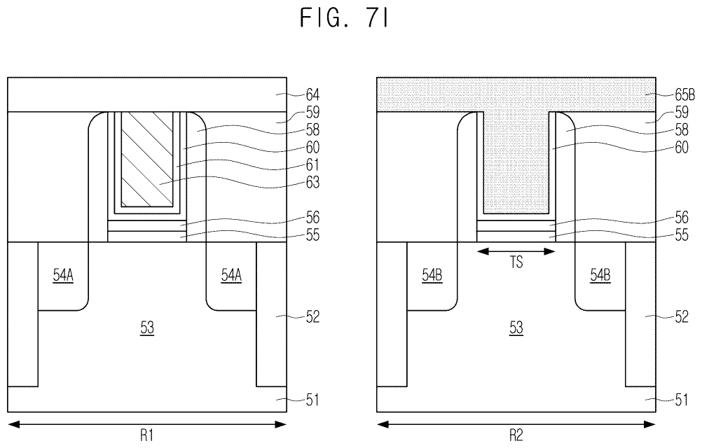

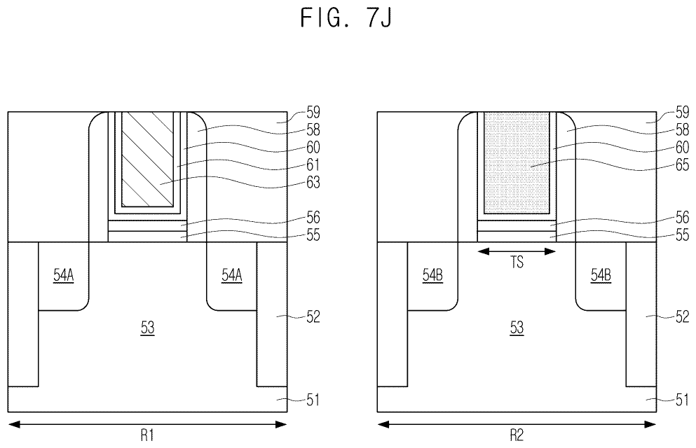

FIGS. 7A to 7J are process cross-sectional views illustrating a method for fabricating the semiconductor device shown in FIG. 6, according to an embodiment of the present disclosure.

Referring to FIG. 7A, the substrate 51 may include an isolation layer 52 and an active region 53 that is defined by the isolation layer 52.

The substrate 51 may include a first region R1 and a second region R2. The first region R1 and the second region R2 may be coupled to each other or may be separated from each other. For example, the first region R1 may be a PMOS region where a P-type transistor is formed, and the second region R2 may be an NMOS region where an N-type transistor is formed, however, the technical concepts and scope of the present disclosure are not limited thereto.

The substrate 51 may be any material suitable for semiconductor processing. The substrate 51 may include a semiconductor substrate.

The substrate 51 may be formed of a material containing silicon. The substrate 51 may include silicon, monocrystalline silicon, polysilicon, amorphous silicon, silicon germanium, carbon-doped silicon, a combination thereof, or a multi-layer thereof. The substrate 51 may also include another semiconductor material, such as germanium. The substrate 51 may also include a III/V-group semiconductor substrate, for example, a compound semiconductor substrate, such as gallium arsenide (GaAs). The substrate 51 may also include an SOI (Silicon-On-Insulator) substrate. According to an embodiment of the present disclosure, the substrate 51 may be an NMOS (N-type Metal Oxide Semiconductor) region.

The isolation layer 52 may be formed by a Shallow Trench Isolation (STI) process including forming an isolation trench (whose reference numeral is omitted) by etching the substrate 51. Then, the isolation trench may be filled with a dielectric material to form the isolation layer 52. The isolation layer 52 may include silicon oxide, silicon nitride, or a combination thereof. Chemical Vapor Deposition (CVD) or another deposition process may be performed to fill the isolation trench with the dielectric material. A planarization process such as Chemical Mechanical Polishing (CMP) may additionally be performed.

A first dummy gate structure including a dummy gate 57 may be formed over the substrate 51 of the first region R1. Also, a second dummy gate structure including a dummy gate 57 may be formed over the substrate 51 of the second region R2. The first and second dummy gate structures may be formed to have the same structure in the first and second regions R1 and R2. Each of the first and second dummy gate structures may include a stacked structure of an interface layer 55, a high-k layer 56, and a dummy gate electrode 57. A gate spacer 58 may be formed on both sides of each of the first and second dummy gate structures to cover the sides of each of the first and second dummy gate structures. The first and second dummy gate structures may be formed through a series of processes of sequentially stacking a dielectric material layer for interface, a high-k material layer, and a polysilicon layer for dummy gates, and etching them. The gate spacer 58 may be formed through a series of processes of forming a dielectric material layer for spacers that covers the first and second dummy gate structures, and then etching the dielectric material layer for forming the spacers.

The stacked structure of the interface layer 55 and the high-k layer 56 may be referred to as a ‘gate dielectric layer.’ The interface layer 55 may include a dielectric material. For example, the interface layer 55 may include silicon oxide, silicon oxynitride, or a combination thereof.

The high-k layer 56 may include a dielectric material having a higher dielectric constant than silicon oxide (SiO₂). The high-k layer 56 may have a dielectric constant of, for example, approximately 10 to approximately 25. The high-k layer 56 may be referred to as a ‘high-k layer.’ For example, the high-k layer 56 may include hafnium oxide, hafnium oxynitride, hafnium silicon oxide, tantalum oxide, titanium oxide, yttrium oxide, lanthanum oxide, lanthanum aluminum oxide, zirconium oxide, zirconium silicon oxide, aluminum oxide, and/or a combination thereof, however, the technical concepts and scope of the present disclosure are not limited thereto.

The dummy gate electrode 57 may include, for example, polysilicon.

The gate spacer 58 may include, for example, silicon oxide or silicon nitride.

First doped regions 54A may be formed in the substrate 51 on both sides of the first dummy gate structure. Also, second doped regions 54B may be formed in the substrate 51 on both sides of the second dummy gate structure. The first doped regions 54A may be formed in the first region R1. The second doped regions 54B may be formed in the second region R2. According to an embodiment of the present disclosure, when the first region R1 is a PMOS region, the first doped regions 54A may be doped with a P-type impurity. Here, an N-type well may be formed in the active region 53. Also, when the second region R2 is an NMOS region, the second doped regions 54B may be doped with an N-type impurity. Here, a P-type well may be formed in the active region 53.

Subsequently, an inter-layer dielectric layer 59 may be formed over the substrate 51 of the first and second regions R1 and R2. The inter-layer dielectric layer 59 may cover the side wall of the gate spacer 57 and expose the upper surfaces of the first and second dummy gate structures. In order to expose the upper surfaces of the first and second dummy gate structures, a planarization process may be performed after the inter-layer dielectric layer 59 is formed. Therefore, the inter-layer dielectric layer 59 may have the same height as those of the first and second dummy gate structures. The upper surface of the inter-layer dielectric layer 59 may be disposed at the same level as the upper surfaces of the first and second dummy gate structures.

The inter-layer dielectric layer 59 may include an oxide. For example, the inter-layer dielectric layer 59 may include silicon oxide, however, the technical concepts and scope of the present disclosure are not limited thereto. According to another embodiment of the present disclosure, the inter-layer dielectric layer 59 may be formed by stacking two or more dielectric layers.

Referring to FIG. 7B, the dummy gate electrode 57 (see FIG. 7A) may be removed from each of the first and second regions R1 and R2. As a result, a trench 57R may be formed between the gate spacers 58 in each of the first and second regions R1 and R2. The trench 57R may expose the side surface of the gate spacers 58 and the upper surface of the high-k layer 56. As the dummy gate electrode 57 is removed, the trench 57R, which is an empty space, may be formed, thereby applying a compressive stress to the channel.

Referring to FIG. 7C, a barrier material layer 60A may be formed in the trenches 57R of the first and second regions R1 and R2. The barrier material layer 60A may be formed conformally along the inner wall and the bottom surface of the trench 57R. The barrier material layer 60A may uniformly cover the upper surface of the high-k layer 56 and the inner wall of the gate spacer 57. For example, the barrier material layer 60A may include tantalum nitride (TaN), however, the technical concepts and scope of the present disclosure are not limited thereto.

Referring to FIG. 7D, a work function material layer 61A may be formed over the barrier material layer 60A of the first region R1. The work function material layer 61A may be formed conformally over the barrier material layer 60A of the first region R1.

The work function material layer 61A may be formed through a series of processes of forming a work function material over the barrier material layer 60A of each of the first region R1 and the second region R2, forming a mask pattern that opens the second region R2, and selectively removing the work function material layer 61A of the second region R2.

The work function material layer 61A may be formed in a liner type over the barrier material layer 60A of the first region R1. According to an embodiment of the present disclosure, when the first region R1 is a PMOS region, the first work function material layer 61A may be a P-type work function control layer. For example, the first work function material layer 61A may include titanium nitride (TIN), however, the technical concepts and scope of the present disclosure are not limited thereto.

Referring to FIG. 7E, a first mask layer 62 that gap-fills the trench 57R may be formed over the barrier material layer 60A of the second region R2.

The first mask layer 62 may be provided to protect the second region R2 when the gate electrode of the first region R1 is formed, and the first mask layer 62 may be referred to as a ‘sacrificial layer’.

Referring to FIG. 7F, a first metal gate structure may be formed in the first region R1.

The first metal gate structure may be formed through a series of processes of forming a gate electrode material over the work function material layer 61A (see FIG. 7E) of the first region R1, and planarizing the gate electrode material to expose the upper surface of the inter-layer dielectric layer 59. Therefore, the first metal gate structure may have the same height as that of the inter-layer dielectric layer 59. The upper surface of the first metal gate structure may be disposed at the same level as the upper surface of the inter-layer dielectric layer 59.

The first metal gate structure may include a stacked structure of an interface layer 55, a high-k layer 56, a barrier layer 60, a work function layer 61, and a first metal gate electrode 63.

For example, the first metal gate electrode 63 may include a low-resistance material, such as tungsten or aluminum. According to another embodiment of the present disclosure, the first metal gate electrode 63 may be a stacked structure of a diffusion barrier layer and a low-resistance material. For example, the diffusion barrier layer may include titanium nitride.

In the planarization process for forming the first metal gate structure, the first mask layer 62A and the barrier material layer 60A (see FIG. 7E) of the second region R2 may be etched together to expose the upper surface of the inter-layer dielectric layer 59 in the second region R2. Hereinafter, the barrier material layer 60A (see FIG. 7D) that is etched by the planarization process may be referred to as a ‘barrier layer 60’.

Referring to FIG. 7G, a second mask layer 64 may be formed over the first metal gate structure and the inter-layer dielectric layer 59 of the first region R1.

Subsequently, the first mask layer 62A (see FIG. 7F) of the second region R2 may be removed to expose the inner wall and the bottom surface of the barrier layer 60 in the trench 57R.

Referring to FIG. 7H, a liquid metal layer 65A that gap-fills the trench 57R may be formed over the barrier layer 60.

The liquid metal layer 65A may include a metal material whose volume is increased when solidified. Also, the liquid metal layer 65A may include a liquid metal material that may be deposited in the liquid state at around the room temperature (e.g., approximately 15° C. to 45° C.). For example, the liquid metal layer 65A may include a gallium-based metal material. For example, the gallium-based metal material may include EGaIn (Eutectic Gallim-Indium), however, the technical concepts and scope of the present disclosure are not limited thereto. Also, the gallium-based metal material may have a melting point that may be adjusted according to the composition ratio of the alloy.

Since the liquid metal layer 65A may be deposited in the liquid state at around the room temperature, a high-temperature process may be unnecessary, and thus the damage to the device that may be caused due to the high-temperature process may be reduced.

Referring to FIG. 7I, the liquid metal layer 65A (see FIG. 7H) may be cooled to form a solid metal layer 65B. The cooling process may be performed at a temperature lower than the temperature at which the liquid metal layer 65A is formed.

The solid metal layer 65B may have a larger volume than the liquid metal layer 65A and, therefore, as it expands during cooling the solid metal layer 65B may apply a tensile stress TS to the channel below the metal gate structure between second doped regions 54B.

Referring to FIG. 7J, a planarization process may be performed onto the solid metal layer 65B (see FIG. 7I) to form a second metal gate structure.

The second metal gate structure may include a stacked structure of an interface layer 55, a high-k layer 56, a barrier layer 60, and a second metal gate electrode 65.

According to an embodiment of the present disclosure, the performance of a semiconductor device may be improved by using a liquid metal material for forming a gate electrode whose volume is increased when solidified and thereby is applying a tensile stress to the channel formed in the substrate below the gate electrode and between doped regions in the substrate.

While the embodiments of the present disclosure have been described with respect to specific embodiments, it will be apparent to those skilled in the art that various changes and modifications may be made without departing from the spirit and scope of the present disclosure as defined in the following claims. Furthermore, the embodiments may be combined to form additional embodiments.

What is claimed is:

1. A semiconductor device comprising:
a gate structure including a gate electrode that is formed over a substrate and includes a metal whose volume is increased when solidified; and
a gate spacer formed on both sides of the gate structure.

2. The semiconductor device of claim 1, wherein the gate electrode includes a gallium-based metal material.

3. The semiconductor device of claim 1, wherein the gate electrode includes EGaIn (Eutectic Gallim-Indium).

4. The semiconductor device of claim 1, wherein the gate structure further includes a gate dielectric layer disposed between the substrate and the gate electrode.

5. The semiconductor device of claim 4, wherein the gate dielectric layer includes a stacked structure including an interface layer and a high-k layer.

6. The semiconductor device of claim 4, further comprising:
a barrier layer and a work function layer disposed between the gate electrode, the gate spacer, and the gate dielectric layer.

7. The semiconductor device of claim 6, wherein the barrier layer includes tantalum nitride, and the work function layer includes TiAl or TiAlC.

8. The semiconductor device of claim 1, further comprising:
a doping region formed in the substrate on both sides of the gate structure.

9. The semiconductor device of claim 1, wherein the substrate is an NMOS (N-type Metal Oxide Semiconductor) region.

10. The semiconductor device of claim 1, wherein the gate electrode applies a tensile stress to a channel formed in the substrate below the gate structure.

11. A semiconductor device comprising:
a substrate including a first region and a second region;
a first gate structure including a first gate electrode over the substrate of the first region; and
a second gate structure including a second gate electrode which is formed of a metal whose volume is increased when solidified over the substrate of the second region.

12. The semiconductor device of claim 11, wherein the second gate electrode includes a gallium-based metal material.

13. The semiconductor device of claim 11, wherein the second gate electrode includes EGaIn (Eutectic Gallim-Indium).

14. The semiconductor device of claim 11, wherein the first gate electrode includes
a stacked structure of a barrier layer, a first work function layer, a second work function layer, and a first metal gate electrode.

15. The semiconductor device of claim 14, wherein the barrier layer includes tantalum nitride, and
the first work function layer includes titanium nitride, and
the second work function layer includes TiAl or TiAlC, and
the first metal gate electrode includes tungsten or aluminum.

16. The semiconductor device of claim 11, wherein the second gate electrode includes
a stacked structure of a barrier layer, a second work function layer, and a second metal gate electrode.

17. The semiconductor device of claim 16, wherein the barrier layer includes tantalum nitride, and the second work function layer includes TiAl or TiAlC.

18. The semiconductor device of claim 11, wherein the first gate structure and the second gate structure further include
first and second gate dielectric layers between the substrate and the first and second gate electrodes, respectively.

19. The semiconductor device of claim 18, wherein each of the first and second gate dielectric layers includes
a stacked structure of an interface layer and a high-k layer.

20. The semiconductor device of claim 11, further comprising:
first and second gate spacers formed on both sides of the first and second gate structures, respectively.

21. The semiconductor device of claim 11, further comprising:
a doping region formed in the substrate on both sides of each of the first and second gate structures.

22. The semiconductor device of claim 11, wherein the first region includes a PMOS (P-type Metal Oxide Semiconductor) region, and
the second region includes an NMOS (N-type Metal Oxide Semiconductor) region.
